(19) United States
(12) Patent Application Publication
(10) Pub. No.: US 2025/0040407 A1
(43) Pub. Date: Jan. 30, 2025

(54) ENCAPSULATION LAYER, DISPLAY PANEL HAVING THE SAME AND DISPLAY DEVICE INCLUDING THE SAME

(71) Applicant: Samsung Display Co., Ltd., Yongin-si (KR)

(72) Inventors: OHJUNE KWON, Yongin-si (KR); SEUNG-YEON CHAE, Yongin-si (KR)

(21) Appl. No.: 18/644,792

(22) Filed: Apr. 24, 2024

(30) Foreign Application Priority Data
Jul. 27, 2023 (KR) 10-2023-0098505

(51) Int. Cl. H10K 59/80; H10K 102/00

(52) U.S. Cl. CPC H10K 59/873; H10K 2102/311

(57) ABSTRACT

A display panel includes a front display area and a bending display area which is bent from the front display area, a base layer corresponding to the front display area and the bending display area, a circuit layer on the base layer, a light emitting element layer on the circuit layer and overlapping the display areas, and an encapsulation layer on the light emitting element layer. The encapsulation layer includes a first thickness portion overlapping the front display area, a second thickness portion overlapping the bending display area, and a first distance from a top surface of the base layer to a top surface of the encapsulation layer at the first thickness portion which is less than a second distance from the top surface of the base layer to a top surface of the encapsulation layer at the second thickness portion.

This application claims priority to Korean Patent Application No. 10-2023-0098505, filed on Jul. 27, 2023, and all the benefits accruing therefrom under 35 U.S.C. § 119, the entire contents of which are hereby incorporated by reference.

### BACKGROUND

### (1) Field

The present disclosure herein relates to a display panel and a display device including the same. More particularly, the present disclosure herein relates to a display panel having improved display quality.

### (2) Description of the Related Art

Display devices are used in various multimedia devices such as televisions, mobile phones, tablet computers, game consoles, and the like to provide image information to a user. Such a display device includes an emissive display panel to provide a picture or images to a user through light generated from a display panel.

The display panel may include a display area which emits light and a non-display area which transmits a signal for driving the display area. Display devices having display areas with various shapes have been developed. In addition, if moisture or oxygen is penetrated from the outside of the display panel, an emission layer of a light emitting element a display area may be deteriorated to cause various defects. Thus, an encapsulation substrate is being used to protect the light emitting element.

### SUMMARY

The present disclosure provides a display panel having improved durability of an encapsulation layer and a display device including the same.

An embodiment of the invention provides a display panel including a base layer including a front area, a display area, which includes a bending area bent downward from a first side of the front area to have a first curvature, and a non-display area adjacent to the display area, a circuit layer disposed on the base layer, a light emitting element layer disposed on the circuit layer and including a light emitting element overlapping the display area, and an encapsulation layer disposed on the light emitting element layer, where the encapsulation layer includes a first encapsulation part overlapping the front area and a second encapsulation layer overlapping the bending area, and a first shortest distance from a top surface of the base layer to a top surface of the first encapsulation part is less than a second shortest distance from the top surface of the base layer to a top surface of the second encapsulation part.

In an embodiment, the top surface of the second encapsulation part may be curved.

In an embodiment, the display area may further include a side area spaced apart from the front area with the bending area therebetween.

In an embodiment, the light emitting element may be configured to generate light in a visible light wavelength range, and the light may be emitted through the front area, the bending area, and the side area.

In an embodiment, the encapsulation layer may further include a third encapsulation part overlapping the side area, and the first shortest distance may be less than a third shortest distance from the top surface of the base layer to a top surface of the third encapsulation part.

In an embodiment, the encapsulation layer may include a first inorganic layer disposed on the light emitting element layer, a first organic layer disposed on the first inorganic layer, and a second inorganic layer disposed on the first organic layer.

In an embodiment, the encapsulation layer may further include a third inorganic layer disposed on the second inorganic layer to overlap the bending area.

In an embodiment, the first shortest distance may be less than the shortest distance from the top surface of the base layer to a top surface of the third inorganic layer.

In an embodiment, the encapsulation layer may further include a second organic layer disposed on the second inorganic layer to overlap the bending area.

In an embodiment, the first shortest distance may be less than the shortest distance from the top surface of the base to a top surface of the second organic layer.

In an embodiment, the second organic layer may entirely overlap the bending area and have a dome shape which is convex in a direction away from the second inorganic layer.

In an embodiment, the encapsulation layer may further include a third inorganic layer disposed on the second organic layer to overlap the bending area, and the first shortest distance may be less than the shortest distance from the top surface of the base layer to a top surface of the third inorganic layer.

In an embodiment, the display area may further include a side area spaced apart from the front area with the bending area therebetween, the second organic layer may include a side part overlapping the side area and a bending part overlapping the bending area, and the shortest distance from the base layer to the side part may be less than the shortest distance from the base layer to the bending part.

In an embodiment, the bending area may include a first bending active area bent downward from the first side of the front area to have the first curvature, and a second bending active area bent from a second side of the front area which is perpendicular to the first side of the front area on a plane to have a second curvature.

In an embodiment, the second encapsulation part may include a second-1 portion overlapping the first bending active area, and a second-2 portion overlapping the second bending active area, where the first shortest distance may be less than each of the shortest distance from the top surface of the base layer to a top surface of the second-1 portion and the shortest distance from the top surface of the base layer to a top surface of the second-2 portion.

In an embodiment, the encapsulation layer may have light transmittance of about 80% or more in a visible light wavelength range.

In an embodiment, the encapsulation layer may be directly disposed on the light emitting element layer.

In an embodiment, the light emitting element may include a first electrode, an emission layer, and a second electrode, which are sequentially disposed on the circuit layer.

In an embodiment of the invention, a display panel includes a base layer including a front area and a first bending area bent from a first side of the front area to have a first curvature, a circuit layer disposed on the base layer, a light emitting element layer disposed on the circuit layer, and an encapsulation layer including a first inorganic layer disposed on the light emitting element layer, a first organic layer disposed on the first inorganic layer, and a second inorganic layer disposed on the first organic layer, where the encapsulation layer includes a first encapsulation part overlapping the front area and a second encapsulation layer overlapping the first bending area, and a first shortest distance from a top surface of the base layer to a top surface of the first encapsulation part is less than a second shortest distance from the top surface of the base layer to a top surface of the second encapsulation part.

In an embodiment of the invention, a display device includes a display panel configured to emit light, an input sensing unit disposed on the display panel, and a window disposed on the input sensing unit, where the display panel includes a base layer including a front area, a display area, which includes a bending area bent downward from a first side of the front area to have a first curvature, and a non-display area adjacent to the display area, a circuit layer disposed on the base layer, a light emitting element layer disposed on the circuit layer and including a light emitting element overlapping the display area, and an encapsulation layer disposed on the light emitting element layer, where the encapsulation layer includes a first encapsulation part overlapping the front area and a second encapsulation layer overlapping the first bending area, and a first shortest distance from a top surface of the base layer to a top surface of the first encapsulation part is less than a second shortest distance from the top surface of the base layer to a top surface of the second encapsulation part.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain embodiments of the invention. In the drawings:

FIG. 1 is a perspective view of a display device according to an embodiment of the invention;

FIG. 2A is an exploded perspective view of the display device according to an embodiment of the invention;

FIG. 2B is a cross-sectional view of an electronic panel according to an embodiment of the invention;

FIG. 3 is a plan view of a display panel according to an embodiment of the invention;

FIG. 4 is an enlarged cross-sectional view of the display panel according to an embodiment of the invention;

FIGS. 5A and 5B are enlarged cross-sectional views of the display panel according to an embodiment of the invention; and

FIGS. 6A to 6D are enlarged cross-sectional views of a display panel according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

In this specification, it will also be understood that when one component (or region, layer, portion) is referred to as being related to another element such as being “on”, “connected to”, or “coupled to” another component, it can be directly disposed/connected/coupled on/to the one component, or an intervening third component may also be present.

Like reference numerals refer to like elements throughout.

Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. Within the Figures and the text of the disclosure, a reference number indicating a singular form of an element may also be used to reference a plurality of the singular element. “At least one” is not to be construed as limiting “a” or “an.” “Or” means “and/or.” The term “and/or” includes any and all combinations of one or more of the associated components.

It will be understood that although the terms such as ‘first’ and ‘second’ are used herein to describe various elements, these elements should not be limited by these terms. These terms are used only to distinguish one component from other components. For example, a first element referred to as a first element in an embodiment can be referred to as a second element in another embodiment without departing from the scope of the appended claims.

The terms of a singular form may include plural forms unless referred to the contrary.

Also, ““under”, “below”, “above’, “upper”, and the like are used for explaining relation association of the elements illustrated in the drawings. The terms may be a relative concept and described based on directions expressed in the drawings.

The meaning of ‘include’ or ‘comprise’ specifies a property, a fixed number, a process, an operation, an element, a component or a combination thereof, but does not exclude other properties, fixed numbers, processes, operations, elements, components or combinations thereof.

In this specification, elements being related such as being “directly disposed,” “directly connected,” and the like may mean that there is no layer, film, area, plate, or the like between a portion of the layer, the film, the area, the plate, or the like and the other portion. For example, “directly disposed” may mean being disposed without using an additional member such and an adhesion member between two layers or two members. As being “directly disposed” and the like, elements may contact each other such as to form an interface therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by a person of ordinary skill in the art to which the invention belongs. In addition, terms such as those defined in commonly used dictionaries should be interpreted as having a meaning consistent with the meaning in the context of the related technology, and unless explicitly defined here, the terms should not be interpreted as too ideal or too formal sense.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

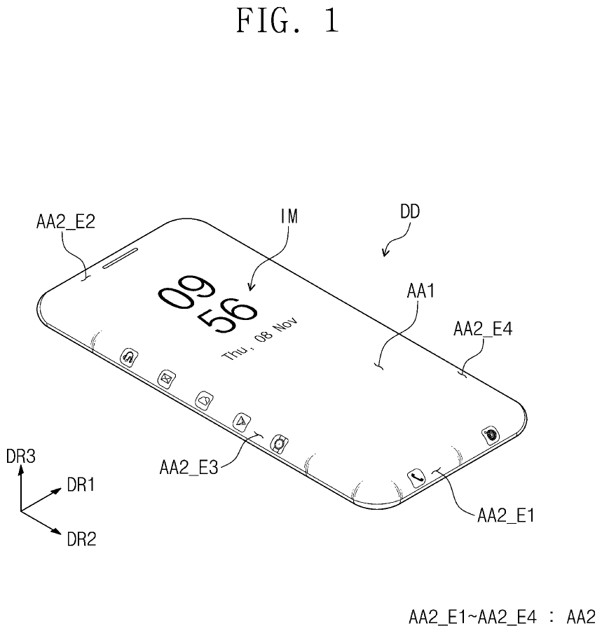

FIG. 1 is a coupling perspective view of a display device DD according to an embodiment of the invention.

In FIG. 1, a smart phone is illustrated as an example of a display device DD. However, the embodiment of the invention is not limited thereto. For example, the display device DD according to an embodiment of the invention may be used for large-sized display devices such as televisions and monitors and small and middle-sized display devices such as mobile phones, tablet personal computer (PC), navigation units for vehicles, game consoles, or smart watches.

Three-dimensional active areas AA1 and AA2 on which an image IM is displayed may be defined on the display device DD. In FIG. 1, the image IM is illustrated as a date, a time, and an icon image.

The active areas AA1 and AA2 on which the image IM is displayed may include a first active area AA1 having a planar shape and a second active area AA2 bent from the first active area AA1. The first and second active areas AA1 and AA2 may be only figuratively divided areas and may substantially implement one unitary display surface.

The first active area AA1 may be parallel to a plane defined by a first direction DR1 and a second direction DR2 crossing each other. A normal direction relative to the first active area AA1 may be parallel to a third direction DR3 crossing each of the first direction DR1 and the second direction DR2. The third direction DR3 may be defined as a direction substantially perpendicular to a plane defined by the first direction DR1 and the second direction DR2. A front surface (or top surface) and a rear surface (or bottom surface) of each of members constituting the display device DD may be opposed to each other in the third direction DR3, and a normal direction of each of the front and rear surfaces may be substantially parallel to the third direction DR3. A spaced distance between the front surface and the rear surface defined along the third direction DR3 may correspond to a thickness of the member (or unit). A thickness of the display device DD and various components or layers thereof may be defined along the third direction, e.g., a thickness direction.

In this specification, the term “on the plane” may be defined as a state when viewed in (or along) the third direction DR3. In this specification, “on the cross-section” may be defined as a state when viewed from the first direction DR1 or the second direction DR2, that is, any of a number of directions along the DR1-DR2 plane. The directions indicated as the first to third directions DR1, DR2, and DR3 may be a relative concept and thus changed into different directions.

The second active area AA2 may be an area which is bent from a side of the first active area AA1 to extend along a planar direction as well as along the thickness direction. The second active area AA2 may be an area bent from the first active area AA1 at a predetermined curvature. Although not separately illustrated in FIG. 1, a bezel area on which the image IM is not displayed may be defined on a partial outer area of the second active area AA2. An outer area of the second active area AA2 may be an edge portion thereof which is furthest from the first active area AA1.

The second active area AA2 may include a first edge active area AA2_E1, a second edge active area AA2_E2, a third edge active area AA2_E3, and a fourth edge active area AA2_E4, which are bent from respective sides of the first active area AA1. The sides of the first active area AA1 may be a boundary between the first active area AA1 and the second active area AA2. The second active area AA2 may include a first edge active area AA2_E1 bent from a first side of the first active area AA1, a second edge active area AA2_E2 bent from a second side of the first active area AA1, a third edge active area AA2_E3 bent from a third side of the first active area AA1, and a fourth edge active area AA2_E4 bent from a fourth side of the first active area AA1. In FIG. 1, the second active area AA2 is illustrated as including the first to fourth edge active areas AA2_E1, AA2_E2, AA2_E3, and AA2_E4, but the number of edge active areas included in the second active area AA2 according to an embodiment of the invention may vary as needed.

Each of the first edge active area AA2_E1, the second edge active area AA2_E2, the third edge active area AA2_E3, and the fourth edge active area AA2_E4 may be bent to have a predetermined curvature in a direction opposite to the third direction DR3 illustrated in FIG. 1. Each of the first edge active area AA2_E1, the second edge active area AA2_E2, the third edge active area AA2_E3, and the fourth edge active area AA2_E4 may have a single curvature.

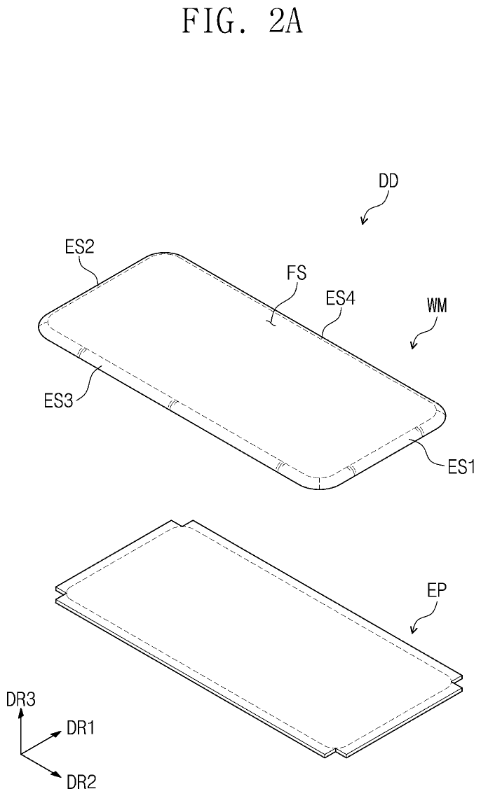

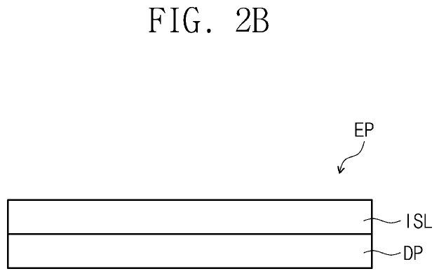

FIG. 2A is an exploded perspective view of the display device DD according to an embodiment of the invention. FIG. 2B is a cross-sectional view of an electronic panel EP according to an embodiment of the invention.

Referring to FIG. 2A, the display device DD may include a window WM and an electronic panel EP which is disposed below the window WM.

The window WM may be disposed on the electronic panel EP. The image IM (see FIG. 1) displayed at the display panel DP may be visible to outside the display device DD, such as to a user, through the window WM. That is, a display surface of the display device DD may be defined by an outer surface of the window WM.

The window WM may include a base member and a bezel pattern which is on the base member. The base member may include a glass substrate, plastic, or a film and may have a single-layered or multi-layered structure. The bezel pattern may be disposed to overlap an outer area of the base member (e.g., a periphery or outer edge), and the bezel pattern may define a bezel area described with reference to FIG. 1. However, if necessary, the bezel pattern may be omitted from the window WM according to an embodiment.

The window WM may be optically transparent. For example, the window WM may include a glass substrate, and specifically, the glass substrate may be a chemically strengthened tempered glass substrate. For example, the window WM may be a single-layered structure including a glass substrate, but is not limited thereto. For example, the window WM may be a multi-layered structure including a coating film coated on a glass substrate, a filling member, or a polymer film disposed on the glass substrate.

The base member of the window WM may include a front active area FS and side active areas ES1, ES2, ES3, and ES4, which are each bent from the front active area FS. The front active area FS may correspond to the first active area AA1, and the side active areas ES1, ES2, ES3, and ES4 may correspond to the first to fourth edge active areas AA2_E1, AA2_E2, AA2_E3, and AA2_E4, respectively. In this specification, meaning “areas correspond to each other” may mean that areas overlap each other and are not limited to the same size or dimensional area.

Referring to FIG. 2B, the electronic panel EP according to an embodiment may include a display panel DP and an input sensor ISL as an input sensing layer which is disposed on the display panel DP. The input sensing layer may include an input sensor.

The display panel DP may generate the image IM (see FIG. 1). The display panel DP according to an embodiment may be a self-luminous display panel. For example, the display panel DP may be a micro light emitting diode (LED) display panel, a nano LED display panel, an organic light emitting display panel, or a quantum dot light emitting display panel. However, this is only an example and is not limited thereto if it is the self-luminous display panel.

An emission layer of the organic light emitting display panel may include an organic light emitting material. An emission layer of the quantum dot light emitting display panel may include a quantum dot and/or a quantum rod. The micro LED display panel may include a micro light emitting diode element, which is an ultra-small light emitting element, and the nano LED display panel may include a nano light emitting diode element. Hereinafter, the organic light emitting display panel will be described as an example of the display panel DP.

The input sensor ISL may be disposed on the display panel DP to acquire coordinate information of an external input. For example, external input may be a user input. The user's input may include various types of external inputs such as light, heat, pressure, proximity, etc., The external input may be provided via an input tool such as a body part like a portion of user's body, a pen, or the like. In an embodiment, the input sensor ISL may be disposed on the display panel DP through a continuous process of a method of providing the electronic panel EP. That is, the input sensor ISL may be disposed directly on the display panel DP. However, the embodiment is not limited thereto, and in another embodiment of the invention, the input sensor ISL may be coupled to the display panel DP through a separate member such as an adhesive member.

Although not shown, the display device DD may further include an optical layer (not shown) disposed between the display panel DP and the input sensor ISL or between the window WM and the electronic panel EP. The optical layer (not shown) may include an anti-reflection member which reduces reflectance of external light incident from the outside.

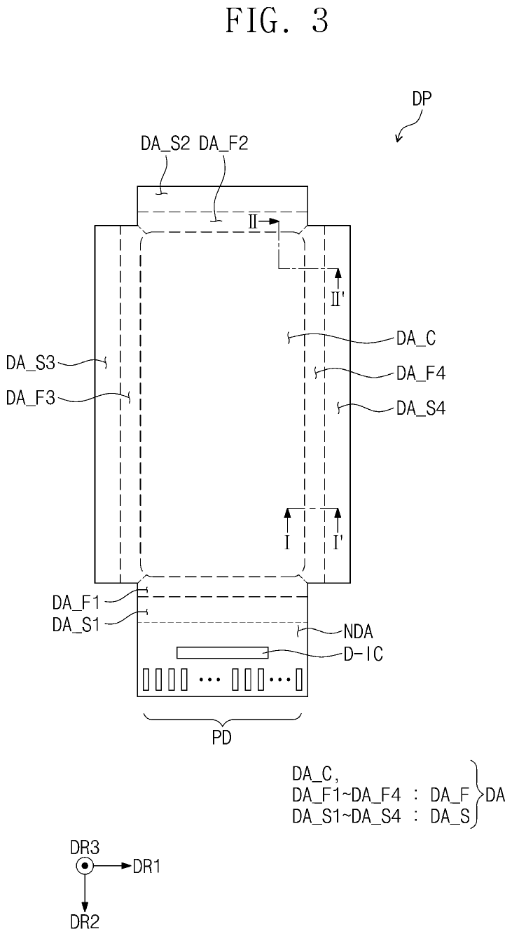

FIG. 3 is a plan view of the display panel DP according to an embodiment of the invention. FIG. 3 does not illustrate the display panel DP in a shape of being inserted into or assembled in the display device DD and having an outer portion which is bent, but illustrates the display panel DP in a shape having a bending area of the display device DD which is unfolded or flat for convenience of explanation.

Referring to FIG. 3, the display panel DP may include the display area DA at which the image IM (see FIG. 1) is displayed and a non-display area NDA at which the image IM (see FIG. 1) is not displayed. The display area DA may be an emission area (e.g., a light emission area) at which pixels are disposed. The display area DA may include a front area DA_C, a bending area DA_F, and a side area DA_S. The front area DA_C, the bending area DA_F, and the side area DA_S may be essentially arranged in a radial direction in flat shape of the display panel DP. That is, the display area DA may include the front area DA_C, the bending area DA_F and a side area DA_S in order.

The front area DA_C, the bending area DA_F, and the side area DA_S may only be geometrically virtually separated areas and may substantially implement one display surface as a unitary surface. The front area DA_C may be parallel to a surface or plane defined by the first direction DR1 and the second direction DR2 crossing each other, such as to have a flat shape. The bending area DA_F may be an area at which the display panel DP is bendable relative to the front area DA_C and/or the side area DA to have a predetermined curvature, and the side area DA_S may be an area extending from the bending area DA_F and spaced apart from the front area DA_C.

The front area DA_C may be an area (e.g., a planar area) corresponding to the front active area FS (see FIG. 2A) of the window WM (see FIG. 2A). Alternatively, the front area DA_C may correspond to a planar area less than a planar area of the front active area FS (see FIG. 2A) of the window WM (see FIG. 2A). That is, a planar area of the front area DA_C may be less than that of the front active area FS (see FIG. 2A) of the window WM.

The bending area DA_F may be defined as an area of the display panel DP at which an intensity of strain or stress applied by bending to have a predetermined curvature is relatively greater than that of other areas of the display area DA. The bending area DA_F may include a first bending area DA_F1, a second bending area DA_F2, a third bending area DA_F3, and a fourth bending area DA_F4, which are each bent from a respective side of the front area DA_C. The bending area DA_F may include a first bending area DA_F1 bent at a first side of the front area DA_C, a second bending area DA_F2 bent at a second side of the front area DA_C, a third bending area DA_F3 bent on a third side of the front area DA_C, and a fourth bending area DA_F4 bent at a fourth side of the front area DA_C.

The first and second sides of the front area DA_C may be substantially parallel to a virtual line in the second direction DR2, and the third and fourth sides of the front area DA_C may be substantially parallel to a virtual line in the first direction DR1. The first and second sides, and the third and fourth sides may be orthogonal to each other on the plane. In this specification, meaning “substantially parallel” may mean not only a case in which the sides do not meet no matter how much the sides extend, but also a case in which an error in process occurs due to a difference in distance between two reference lines even though the sides are designed to be parallel to each other.

The first bending area DA_F1 may be bent to have a first curvature, the second bending area DA_F2 may be bent to have a second curvature, the third bending area DA_F3 may be bent to have a third curvature, and the fourth bending area DA_F4 may be bent to have a fourth curvature. The curvatures of the first bending area DA_F1, the second bending area DA_F2, the third bending area DA_F3, and the fourth bending area DA_F4 may be substantially the same. Alternatively, the curvatures of each of the first bending area DA_F1, the second bending area DA_F2, the third bending area DA_F3, and the fourth bending area DA_F4 may be partially the same or partially different. For example, the first curvature of the first bending area DA_F1 and the second curvature of the second bending area DA_F2 may be substantially the same, and the third curvature of the third bending area DA_F3 and the fourth curvature of the fourth bending area DA_F4 may be substantially the same. In the present specification, meaning “substantially the same” may include not only a case in which refractive indexes and thicknesses of the components are physically completely the same, but also a case in which there is a difference by an error range occurring in process in spite of the same design.

The first bending area DA_F1, the second bending area DA_F2, the third bending area DA_F3, and the fourth bending area DA_F4 may be areas corresponding to the first to fourth side areas ES1, ES2, ES3, and ES4 of the window WM (see FIG. 2A). Alternatively, a portion of each of the first bending area DA_F1, the second bending area DA_F2, the third bending area DA_F3, and the fourth bending area DA_F4 may correspond to an edge portion of the front active area FS (see FIG. 2A) of the window WM (see FIG. 2A), and the other portion of each of the first bending area DA_F1, the second bending area DA_F2, the third bending area DA_F3, and the fourth bending area DA_F4 may correspond to each of the first to fourth side areas ES1, ES2, ES3, and ES4 (see FIG. 2A) of the window WM (see FIG. 2A).

In FIG. 3, the bending area DA_F is illustrated in an unfolded state with respect to the front area DA_C, such that the bending area DA_F may be coplanar with the front area DA_C. However, in the display device DD (see FIG. 1), the display panel DP may be in a state of being variously bent at the bending area DA_F in a direction opposite to the third direction DR3 to correspond to the first to fourth side areas ES1, ES2, ES3, and ES4 (see FIG. 2A) of the window WM which are curved or bent (see FIG. 2A).

The side area DA_S may include a first side area DA_S1, a second side area DA_S2, a third side area DA_S3, and a fourth side area DA_S4, which extend from the bending area DA_F. The side area DA_S may define an outer edge of the display panel DP. The side area DA_S may include a first side area DA_S1 extending from the first bending area DA_F1, a second side area DA_S2 extending from the second bending area DA_F2, a third side area DA_S3 extending from the third bending area DA_F3, and a fourth side area DA_S4 extending from the fourth bending area DA_F4. The first side area DA_S1, the second side area DA_S2, the third side area DA_S3, and the fourth side area DA_S4 may be areas corresponding to the first to fourth side areas ES1, ES2, ES3, and ES4 (see FIG. 2A) of the window WM (see FIG. 2A).

The first side area DA_S1, the second side area DA_S2, the third side area DA_S3, and the fourth side area DA_S4 may have first to fourth curvatures with respect to the front area DA_C, respectively. The side area DA_S may have a first, second, third, or fourth curvature, but may be an area in which bending strain is relatively small compared to the bending strain at the bending area DA_F.

A driving chip D-IC and pads PD may be disposed on the non-display area NDA. The driving chip D-IC may be mounted on the display panel DP and connected to the display area DA, to provide an electrical signal such as a driving signal to the display area DA of the display panel DP. The display panel DP may be foldable, bendable, rollable, etc. at the non-display area NDA. The display panel DP which is bent at the non-display area NDA may include a portion of the non-display area NDA at a rear surface of the display panel DP and disposed under the rear surface of the display panel DP. However, the embodiment is not limited thereto, and the display device DD according to another embodiment may further include an external component such as a printed circuit board (not shown) connected to the display panel DP (such as at the pads PD), and the driving chip D-IC may be mounted on the printed circuit board.

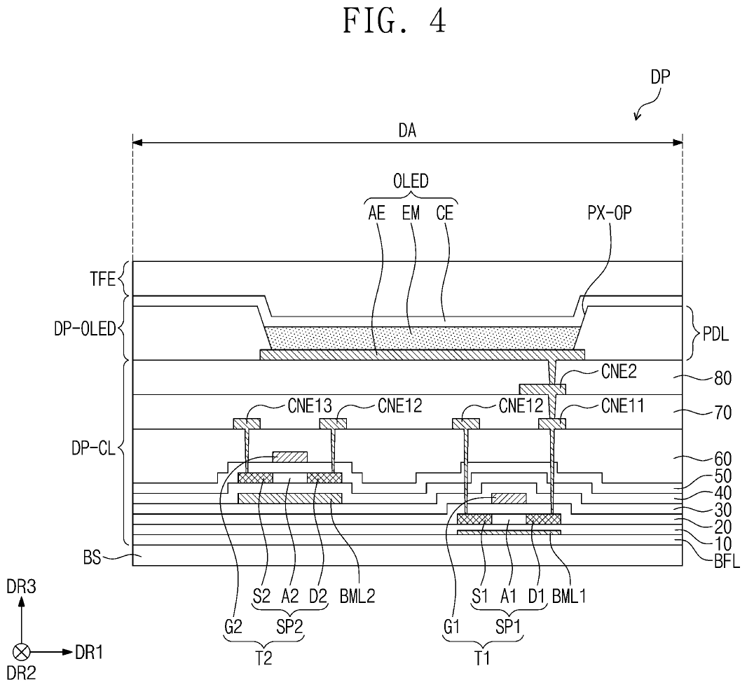

FIG. 4 is a cross-sectional view of the display panel DP according to an embodiment of the invention. FIG. 4 is an enlarged cross-sectional view of a circuit layer and a light emitting element layer in the display panel DP.

Referring to FIG. 4, the display panel DP according to an embodiment may include a base layer BS, a circuit layer DP-CL disposed on the base layer BS, and a light emitting element layer DP-OLED disposed on the circuit layer DP-CL and including a light emitting element OLED.

The base layer BS may be a member which provides a base surface on which the circuit layer DP-CL is disposed. The base layer BS may be a rigid substrate or a flexible substrate capable of being bent, folded, or rolled. The base layer BS may be a substrate containing a resin. For example, the base layer BS may include a polyimide-based resin. However, the embodiment of the invention is not limited thereto, and the base layer BS may be an inorganic layer or a composite material layer.

The circuit layer DP-CL may be disposed on the base layer BS. In an embodiment, the circuit layer DP-CL may include a buffer layer BFL, first to eighth insulating layers 10, 20, 30, 40, 50, 60, 70, and 80, light blocking patterns BML1 and BML2, transistors T1 and T2, and connection electrodes CNE11, CNE12, CNE13, and CNE2.

The buffer layer BFL may be disposed on the base layer BS. The buffer layer BFL may prevent metal atoms or impurities from being diffused from the base layer BS to the upper transistors T1 and T2.

Each of the buffer layer BFL together with one or more insulating layer such as first to eighth insulating layers 10 to 80. The first to eighth insulating layers 10 to 80 may include an inorganic layer and/or an organic layer and may have a single-layered or multi-layered structure. The inorganic layer may include at least one of aluminum oxide, titanium oxide, silicon oxide, silicon nitride, silicon oxynitride, zirconium oxide and hafnium oxide. However, the material of the inorganic layer is not limited to the above example. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin and a perylene-based resin. However, the material of the organic layer is not limited to the above example. However, the insulating layers included in the circuit layer DP-CL are not limited thereto and may vary depending on a configuration of a pixel driving circuit included in the circuit layer DP-CL and a process of providing elements of the circuit layer DP-CL.

A first light blocking pattern BML1 among patterns of a first light blocking layer may be disposed on the buffer layer BFL. When the buffer layer BFL is omitted, the first light blocking pattern BML1 may be directly disposed on the base layer BS. The first light blocking pattern BML1 may include molybdenum. The first light blocking pattern BML1 may perform a shielding function.

The first light blocking pattern BML1 may be disposed on the first insulating layer 10 and covered by the second insulating layer 20 and the third insulating layer 30. The second light blocking pattern BML2 among patterns of a second light blocking layer may be disposed on the third insulating layer 30. The second light blocking pattern BML2 may perform a shielding function (e.g., a light shielding function). The second light blocking pattern BML2 may be disposed on the fourth insulating layer 40 and covered by the fifth insulating layer 50 and the sixth insulating layer 60.

The first transistor T1 may include a first semiconductor pattern SP1 disposed on the first insulating layer 10. The first semiconductor pattern SP1 may include a first source S1, a first active region A1, and a first drain D1. The transistor T1 may include a first gate G1 disposed on the second insulating layer 20. Although not shown, an upper capacitor electrode may be disposed on the first gate G1, and the first gate G1 and the upper capacitor electrode may constitute a storage capacitor.

The second transistor T2 may include a second semiconductor pattern SP2 disposed on the fourth insulating layer 40. The second semiconductor pattern SP2 may include a second source S2, a second active A2, and a second drain D2. The second transistor T2 may include a second gate G2 disposed on the fifth insulating layer 50.

Although two transistors T1 and T2 are illustrated in FIG. 4 for convenience, a plurality of additional transistors connected to the transistors T1 and T2 may be further disposed within the circuit layer DP-CL.

The first-1 connection electrode CNE11 may be connected to the first drain D1 of the first transistor T1. The first-1 connection electrode CNE11 may be connected to the first drain D1 through a contact hole passing through the second to sixth insulating layers 20 to 60. The first-2 connection electrode CNE12 may be connected to the first source S1 of the first transistor T1. The first-2 connection electrode CNE12 may be connected to the first source S1 through a contact hole passing through the second to sixth insulating layers 20 to 60. The first-2 connection electrode CNE12 at the first transistor T1 may extend along the plane to overlap the second drain D2 of the second transistor T2. The first-2 connection electrode CNE12 may be connected to the second drain D2 through a contact hole passing through the fifth and sixth insulating layers 50 and 60. The first-3 connection electrode CNE13 may be connected to the second source S2 of the second transistor T2. The first-3 connection electrode CNE13 may be connected to the second source S2 through a contact hole passing through the fifth and sixth insulating layers 50 and 60.

The first-1st to first-3rd connection electrodes CNE11 to CNE13 within a first connection electrode layer may be covered by the seventh insulating layer 70. The second connection electrode CNE2 of a second connection electrode layer may be connected to the first-1 connection electrode CNE11 through a contact hole passing through the seventh insulating layer 70. The second connection electrode CNE2 may be connected to the first drain D1 of the first transistor T1 through the first-1 connection electrode CNE11. The second connection electrode CNE2 may be covered by the eighth insulating layer 80. However, the embodiment is not limited thereto, and the second connection electrode CNE2 may be omitted, or an additional connection electrode disposed between the second connection electrode CNE2 and the first-1 connection electrode CNE11 in the circuit layer DP-CL may be further provided.

The light emitting element layer DP-OLED may be disposed on the circuit layer DP-CL. The light emitting element layer DP-OLED may include a light emitting element OLED and a pixel defining layer PDL.

The light emitting element OLED may include a first electrode AE, a second electrode CE facing the first electrode AE, and an emission layer EM disposed between the first electrode AE and the second electrode CE. In FIG. 4, one light emitting element OLED is illustrated as an example, but the display panel DP is not limited thereto and may include two or more light emitting elements OLED. Additionally, two or more light emitting elements OLED may emit light having the same wavelength or emit light having different wavelengths. In an embodiment, the light emitting element OLED may generate light in a visible light wavelength range and the light may be emitted through the front area DA_C, the bending area DA_F, and the side area DA_S of the display area DA.

The first electrode AE may be a transmissive electrode, a transflective electrode, or a reflective electrode. According to an embodiment of the invention, the first electrode AE may include at least one selected from Ag, Mg, Cu, Al, Pt, Pd, Au, Ni, Nd, Ir, Cr, Li, Ca, LiF, Mo, Ti, W, In, Sn, and Zn, two or more kinds of compounds selected from the above-described materials, a combination of two or more kinds of above-described materials and oxides thereof.

When the first electrode AE is a transmissive electrode, the first electrode AE may include a transparent metal oxide, for example, indium tin oxide (ITO), indium zinc oxide (IZO), zinc oxide (ZnO), or indium tin zinc oxide (ITZO), and the like. When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (laminated structure of LiF and Ca), LiF/Al (laminated structure of LiF and Al), Mo, Ti, or a compound or combination (e.g., a combination of Ag and Mg) thereof. Alternatively, the first electrode AE may include the reflective layer or transflective layer, which is made of the above-described material, and a transparent conductive film including indium tin oxide (ITO), indium zinc oxide (IZO), zinc oxide (ZnO), or indium tin zinc oxide (ITZO). For example, the first electrode AE may include a three-layered structure of ITO/Ag/ITO, but is not limited thereto.

The emission layer EM may be disposed on the first electrode AE. The emission layers EM of the light emitting elements OLED may be disposed to correspond to the light emitting openings PX-OP, respectively, and may be provided as light emitting patterns spaced apart from each other on the plane. However, the embodiment of the invention is not limited thereto, and the emission layers EM of the light emitting elements OLED may be provided as an integrated film so as to be provided as a common layer. The emission layer EM may include an organic light emitting material and/or an inorganic light emitting material. For example, the emission layer EM may include a fluorescent material, a phosphorescent material, a metal organic complex light emitting material, or quantum dots. The emission layer EM may emit color light having one of red, green, and blue colors.

The second electrode CE may include at least one selected from Ag, Mg, Cu, Al, Pt, Pd, Au, Ni, Nd, Ir, Cr, Li, Ca, LiF, Mo, Ti, W, In, Sn, and Zn, two or more kinds of compounds selected from the above-described materials, a combination of two or more kinds of above-described materials and oxides thereof.

The second electrode CE may be a transmissive electrode, a transflective electrode, or a reflective electrode. When the second electrode CE is the transmissive electrode, the second electrode CE may be made of transparent metal oxide, for example, indium tin oxide (ITO), indium zinc oxide (IZO), zinc oxide (ZnO), or indium tin zinc oxide (ITZO).

When the second electrode CE is the transflective electrode or the reflective electrode, the second electrode CE may include Ag, Mg, Cu, Al, Pt, Pd, Au, Ni, Nd, Ir, Cr, Li, Ca, LiF/Ca (laminated structure of LiF and Ca), LiF/Al (laminated structure of LiF and Al), Mo, Ti, Yb, W, or a compound or combination (e.g., a combination of AgMg, AgYb, or MgYb) thereof. Alternatively, the second electrode CE may include the reflective layer or transflective layer, which is made of the above-described material, and a transparent conductive film including indium tin oxide (ITO), indium zinc oxide (IZO), zinc oxide (ZnO), or indium tin zinc oxide (ITZO). For example, the second electrode CE may include the above-described metal material, a combination of two or more metal materials selected from the above-described metal materials, or oxide of the above-described metal materials.

The pixel defining layer PDL may be disposed on the eighth insulating layer 80 to cover a portion of the first electrode AE of the light emitting element OLED. The pixel defining layer PDL may include material portions which are spaced apart from each other to define a pixel opening PX-OP therebetween. The pixel openings PX-OP may correspond to light emission areas of the display panel DP within the display area DA at which light is emitted from the display panel DP. That is, the pixel defining layer PDL may expose a portion of the first electrode AE. The light emitting openings PX-OP which overlap the first electrode AE and expose a portion of the corresponding first electrode AE to outside the pixel defining layer PDL may be defined in the pixel defining layer PDL.

The pixel define layer PDL may include a polymer resin. For example, the pixel define layer PDL may include a polyacrylate-based resin a polyimide-based resin. The embodiment of the invention is not limited thereto, and the pixel defining layer PDL may further include an inorganic material. The pixel defining layer PDL may further include a light absorbing material. For example, the pixel defining layer PDL may include a black coloring agent such as a black dye or a black pigment. For example, the black component may include a carbon black, a metal such as chromium, or oxide thereof. However, an embodiment of the invention is not limited thereto.

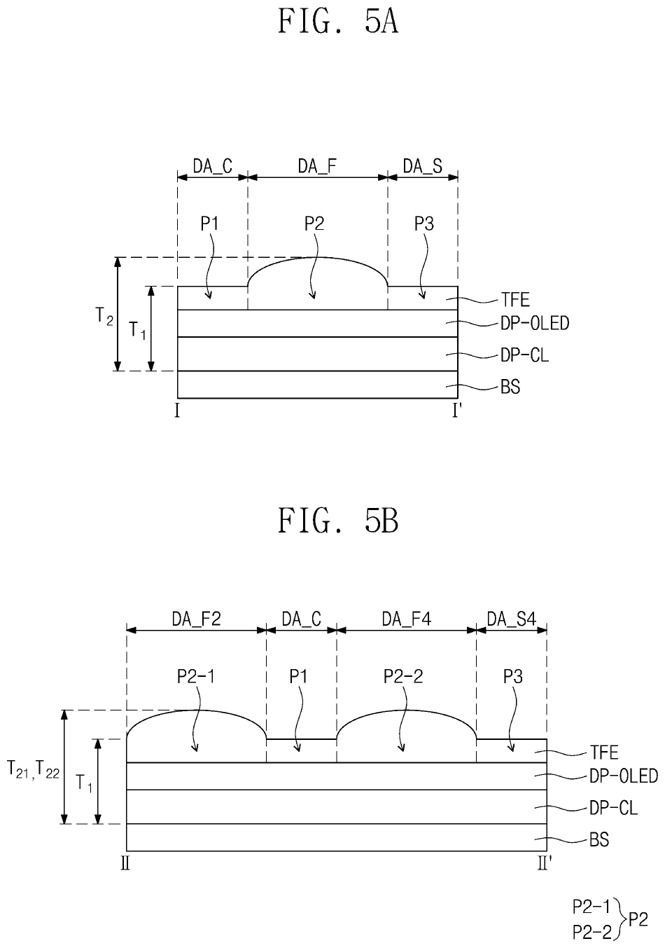

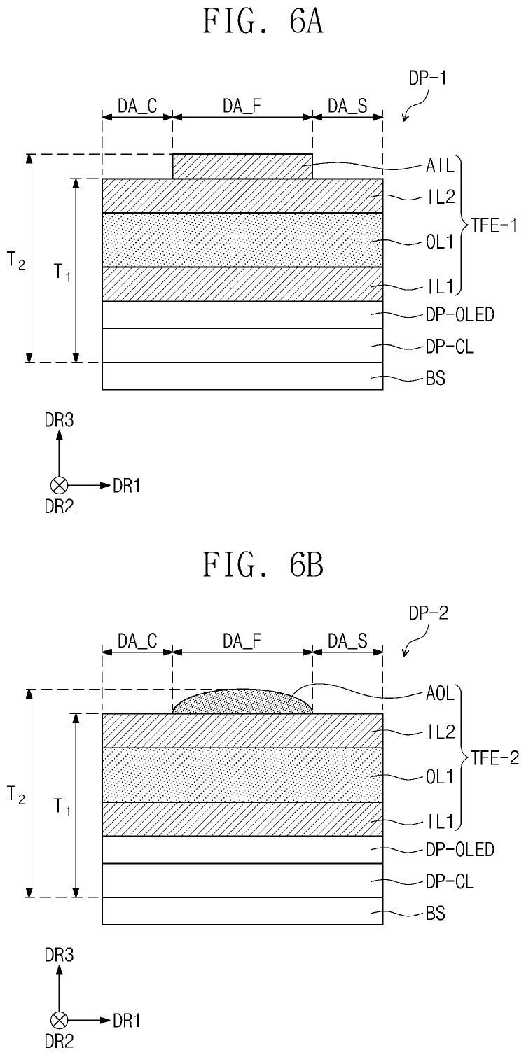

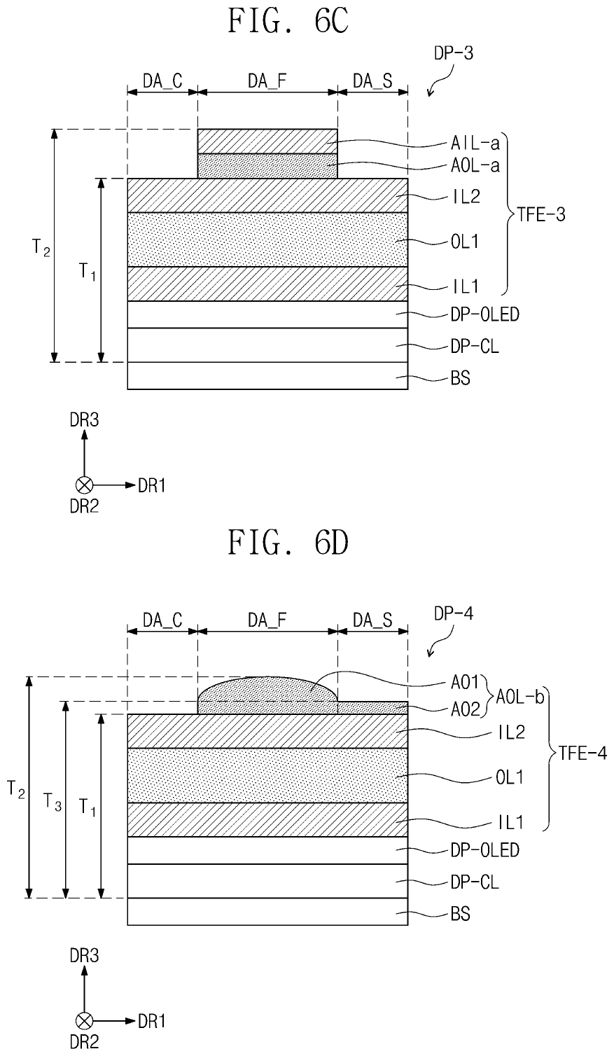

The encapsulation layer TFE may be disposed on the light emitting element layer DP-OLED. The encapsulation layer TFE may seal the light emitting element OLED. The encapsulation layer TFE may include at least one thin film of an inorganic layer and an organic layer. In an embodiment, the encapsulation layer TFE may include inorganic layers and an organic layer disposed between the inorganic layers. The inorganic film of the encapsulation layer TFE may protect the light emitting element OLED from moisture and/or oxygen. The organic layer of the encapsulation layer TFE may protect the light emitting element OLED from foreign substances such as dust particles. In an embodiment, the encapsulation layer TFE may have light transmittance of about 80% or more in a visible light wavelength range. A detailed description of the encapsulation layer TFE will be described later with reference to FIGS. 5 and 6A to 6D.

FIGS. 5A, 5B, and 6A to 6D are cross-sectional views of the display panel DP according to embodiment of the invention. FIG. 5A is a cross-sectional view taken along line I-I′ of FIG. 3, and FIG. 5B is a cross-sectional view taken along line II-II′ of FIG. 3. FIGS. 5A and 5B are enlarged views illustrating the encapsulation layer TFE in the display panel DP which is flat. FIGS. 6A to 6D are enlarged views illustrating specific component and characteristics of the encapsulation layer TFE.

Referring to FIG. 5A, the encapsulation layer TFE may include a first encapsulation part P1 overlapping the front area DA_C, and a second encapsulation part P2 overlapping the bending area DA_F. The encapsulation layer TFE may include an upper surface at each of a first thickness portion (e.g., the first encapsulation part P1) and a second thickness portion (e.g., the second encapsulation part P2). The upper surface at the second encapsulation part P2 overlapping the bending area DA_F may have a curvature which is substantially the same as the curvature of the bending area DA_F. The encapsulation layer TFE may further include a third encapsulation part P3 as a third thickness portion overlapping the side area DA_S. That is, a thickness of the encapsulation layer TFE in a display panel DP which is flat or unbent, varies in a direction from the front area DA_C to the side area DA_S.

A first shortest distance T₁ as a first distance from a top surface of the base layer BS to a top surface of the encapsulation layer TFE at the first encapsulation part P1 may be less than a second shortest distance T₂ as a second distance from the top surface of the base layer BS to a top surface of the encapsulation layer TFE at the second encapsulation part P2. The first shortest distance T₁ may be less than a third shortest distance from the top surface of the base layer BS to a top surface of the encapsulation layer TFE at the third encapsulation part P3.

As used herein, “shortest distance” may be a vertical distance measured along the normal direction perpendicular to a tangent of a measurement point. For example, when each of the top surface of the base layer BS and the top surface of the first encapsulation part P1 is parallel to a plane defined by the first direction DR1 and the second direction DR2 intersecting each other, the first shortest distance T₁ may mean a distance between the top surface of the base layer BS and the top surface of the first encapsulation part P1, which is measured in the third direction DR3. In an embodiment, for the various distances between the top surfaces described above, a maximum of the first distance may be smaller than both a minimum of the second distance and a minimum of the third distance.

In an embodiment, for example, a display panel may include a display area DA including a front area DA_C and a bending area DA_F which is bent from a side of the front area DA_C to have a curvature, and a non-display area NDA which is adjacent to the display area DA, a base layer BS corresponding to the display area DA at the front area DA_C and at the bending area DA_F, a circuit layer DP-CL on the base layer BS, a light emitting element layer DP-OLED on the circuit layer DP-CL, the light emitting element layer DP-OLED, and an encapsulation layer TFE on the light emitting element layer DP-OLED. The encapsulation layer TFE a first thickness portion (e.g., TFE at DA_C) overlapping the front area DA_C), a second thickness portion (e.g., TFE at DA_F) overlapping the bending area DA_F, and a first distance (distance T₁) from a top surface of the base layer BS to a top surface of the encapsulation layer TFE at the first thickness portion which is less than a second distance (distance T₂) from the top surface of the base layer BS to a top surface of the encapsulation layer TFE at the second thickness portion. The encapsulation layer TFE may further include a third thickness portion (e.g., TFE at DA_S) overlapping the side area DA_S, and the first distance which is less than a third distance (distance T₂) from the top surface of the base layer BS to a top surface of the encapsulation layer TFE at the third thickness portion.

Referring to FIG. 5B, the second encapsulation part P2 of the encapsulation layer TFE according to an embodiment may include a second-1 portion P2-1 overlapping the second bending area DA_F2, and a second-2 portion P2-2 overlapping the fourth bending portion DA_F4 which is adjacent to the second bending area DA_F2 and meets the second bending area DA_F2 at a corner of the display panel DP. The second bending area DA_F2 may be referred to as a “first bending active area,” and the fourth bending area DA_F4 may be referred to as a “second bending active area.”

The first shortest distance T₁ from the top surface of the base layer BS to the top surface of the encapsulation layer TFE at the first encapsulation part P1 may be less than each of the shortest distance T₂₁ from the top surface of the base layer BS to a top surface of the encapsulation layer TFE at the second-1 portion P2-1 and the shortest distance T₂₂ from the top surface of the base layer BS to a top surface of the encapsulation layer TFE at the second-2 portion P2-2. In FIG. 5B, the shortest distance T₂₁ from the top surface of the base layer BS to the top surface of the encapsulation layer TFE at the second-1 portion P2-1 and the shortest distance T₂₂ from the top surface of the encapsulation layer TFE at the second-2 portion P2-2 may be illustrated as being substantially the same, but in another embodiment, as necessary, the shortest distance T₂₁ from the top surface of the base layer BS to the top surface of the encapsulation layer TFE at the second-1 portion P2-1 and the shortest distance T₂₂ from the top surface of the base layer BS to the top surface of the encapsulation layer TFE at the second-2 portion P2-2 may have different values.

In FIG. 5B, the encapsulation layer TFE at the second-1 portion P2-1 overlapping the second bending area DA_F2 and the encapsulation layer TFE at the second-2 portion P2-2 overlapping the fourth bending area DA_F4, taken along line II-II′ of FIG. 3, are illustrated as an example, but the same content as the above description may be applied to the portion of the encapsulation layer TFE overlapping the first bending area DA_F1 and the portion of the encapsulation layer TFE overlapping the third bending area DA_F3 which are adjacent to each other along a periphery of the display panel DP. For example, in the display panel DP according to an embodiment, each of the shortest distance from the top surface of the base layer BS to the top surface of the portion overlapping the first bending area DA_F1 (see FIG. 3), the shortest distance from the top surface of the base layer BS to the top surface of the portion overlapping the second bending area DA_F2 (see FIG. 3), the shortest distance from the top surface of the base layer BS to the top surface of the portion overlapping the third bending area DA_F3 (see FIG. 3), and the shortest distance from the top surface of the base layer BS to the top surface of the portion overlapping the fourth bending area DA_F4 (see FIG. 3) may be less than the first shortest distance T₁.

As shown in FIG. 3, the bending area DA_F at which a direction of extended portions of the bending area DA_F changes direction in the plan view. Where extended portions of the side area DA_S are disconnected from each other at corners of the display panel DP in FIG. 3, extended potions of the bending area DA_F are connected to each other at the corners of the display panel DP. A virtual boundary between adjacent extended portions of the bending area DA_F is shown as a dotted line in FIG. 3. In an embodiment, A same thickness of the encapsulation layer TFE as one of the second-1 portion P2-1 and the second-2 portion P2-2 may extend along the corner of the front area DA_C, however, is not limited thereto. In an embodiment, a first thickness (e.g., the shortest distance T₂₁ from the top surface of the base layer BS to a top surface of the encapsulation layer TFE at the second-1 portion P2-1) and a second thickness (e.g., the shortest distance T₂₂ from the top surface of the base layer BS to a top surface of the encapsulation layer TFE at the second-2 portion P2-2) may be respectively extended to the boundary between adjacent bending area portions.

The encapsulation layer TFE according to an embodiment may include at least one inorganic material layer and at least one organic material layer. Referring to FIGS. 6A to 6D, the encapsulation layer TFE-1, TFE-2, TFE-3, and TFE-4 may include a first inorganic layer IL1 disposed on the light emitting element layer DP-OLED, a first organic layer OL1 disposed on the first inorganic layer IL1, and a second inorganic layer IL2 disposed on the first organic layer OL1. That is, within the encapsulation layer TFE, a first inorganic layer IL1, a first organic layer OL1 and a second inorganic layer IL2 may be in order from the light emitting element layer DP-OLED.

Each of the first inorganic layer IL1 and the second inorganic layer IL2 may protect the light emitting elements OLED from moisture and/or oxygen. Each of the first inorganic layer IL1 and the second inorganic layer IL2 may include at least one of aluminum oxide, titanium oxide, silicon oxide, silicon nitride, silicon oxynitride, zirconium oxide and hafnium oxide. However, the material of each of the first inorganic layer IL1 and the second inorganic layer IL2 are not limited to the above examples.

The first organic layer OL1 disposed between the first inorganic layer IL1 and the second inorganic layer IL2 may protect the light emitting elements OLED from foreign substances such as dust particles. The first organic layer OL1 may include an acrylic resin. However, the material of the first organic layer OL1 is not limited to the above example.

Referring to FIG. 6A, the display panel DP-1 according to an embodiment may include an encapsulation layer TFE-1, and the encapsulation layer TFE-1 may further include a third inorganic layer AIL as an inorganic pattern disposed on the second inorganic layer IL2. The third inorganic layer AIL may overlap the bending area DA_F. The third inorganic layer AIL may not overlap the front area DA_C, such as to be adjacent thereto or spaced apart therefrom in a direction along the encapsulation layer TFE. The third inorganic layer AIL may overlap only the bending area DA_F, such as overlapping an entirety thereof. Thus, a second shortest distance T₂ from the top surface of the base layer BS to the top surface of the second encapsulation part P2 (see FIG. 5A) may mean the shortest distance from the top surface of the base layer BS to a top surface of the third inorganic layer AIL which defines the uppermost surface of the encapsulation layer TFE. In the encapsulation layer TFE-1 according to an embodiment, the first shortest distance T₁ may be less than the second shortest distance T₂, which is the shortest distance from the top surface of the base layer BS to the top surface of the third inorganic layer AIL.

Referring to FIG. 6B, the display panel DP-2 according to an embodiment may include an encapsulation layer TFE-2, and the encapsulation layer TFE-2 may further include a second organic layer AOL as an organic pattern disposed on the second inorganic layer IL2. The second organic layer AOL may overlap the bending area DA_F. The second organic layer AOL may not overlap the front area DA_C and may overlap only the bending area DA_F. Thus, the second shortest distance T₂ from the top surface of the base layer BS to the top surface of the second encapsulation part P2 (see FIG. 5A) may mean a shortest distance from the top surface of the base layer BS to a top surface of the second organic layer AOL which defines the uppermost surface of the encapsulation layer TFE. In the encapsulation layer TFE-2 according to an embodiment, the first shortest distance T₁ may be less than the second shortest distance T₂, which is the shortest distance from the top surface of the base layer BS to the top surface of the second organic layer AOL.

The second organic layer AOL may have a dome shape in cross-section which is convex in a direction away from the second inorganic layer IL2. However, the shape of the second organic layer AOL is not limited to the curved convex dome shape as illustrated in FIG. 6B, and the second organic layer AOL may have various shapes as necessary. The second organic layer AOL may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin and a perylene-based resin. However, the material contained in the second organic layer AOL is not limited to the above example, and any organic material which is capable of providing a weakening of the bending strain or bending stress of the second inorganic layer IL2 may be contained in the second organic layer AOL without limitation.

Referring to FIG. 6C, the display panel DP-3 according to an embodiment may include an encapsulation layer TFE-3, and the encapsulation layer TFE-3 may further include a second organic layer AOL-a disposed on the second inorganic layer IL2 and a third inorganic layer AIL-a disposed on the second organic layer AOL-a. The second organic layer AOL-a and the third inorganic layer AIL-a may overlap the bending area DA_F. The second organic layer AOL-a and the third inorganic layer AIL-a may be sequentially laminated on the second inorganic layer IL2 to overlap the bending area DA_F. The second organic layer AOL-a and the third inorganic layer AIL-a may not overlap the front area DA_C and may only overlap the bending area DA_F. Thus, a second shortest distance T₂ from the top surface of the base layer BS to the top surface of the second encapsulation part P2 (see FIG. 5A) may mean a shortest distance from the top surface of the base layer BS to a top surface of the third inorganic layer AIL-a which defines the uppermost surface of the encapsulation layer TFE. In the encapsulation layer TFE-3 according to an embodiment, the first shortest distance T₁ may be less than the second shortest distance T₂, which is the shortest distance from the top surface of the base layer BS to the top surface of the third inorganic layer AIL-a.

Referring to FIG. 6D, the display panel DP-4 according to an embodiment may include an encapsulation layer TFE-4, and the encapsulation layer TFE-4 may further include a second organic layer AOL-b disposed on the second inorganic layer IL2. The second organic layer AOL-b may not overlap the front area DA_C and may overlap the bending area DA_F. The second organic layer AOL-b may extend from the bending area DA_F to also overlap the side area DA_S. That is, the second organic layer AOL-b may include a bending part AO1 overlapping the bending area DA_F and a side part AO2 which extends from the bending part AO1 and overlaps the side area DA_S. The second shortest distance T₂ from the top surface of the base layer BS to the top surface of the second encapsulation part P2 (see FIG. 5A) may mean a shortest distance from the top surface of the base layer BS to a top surface of the bending part AO1 which defines the uppermost surface of the encapsulation layer TFE.

A third shortest distance T₃ as a third distance from the top surface of the base layer BS to the top surface of the third encapsulation part P3 (see FIG. 5A) may mean the shortest distance from the top surface of the base layer BS to a top surface of the side part AO2. In the encapsulation layer TFE-4 according to an embodiment, the first shortest distance T₁ may be less than the second shortest distance T₂, which is the shortest distance from the top surface of the base layer BS to the top surface of the bending part AO1, and the third shortest distance T₃ which is the shortest distance from the top surface of the base layer BS to the top surface of the side part AO2 may be less than the second shortest distance T₂ which is the shortest distance from the top surface of the base layer BS to the top surface of the bending part AO1.

The display panel DP according to an embodiment of the invention includes portions having different thicknesses within one encapsulation layer TFE. Specifically, the encapsulation layer TFE according to an embodiment may have a relatively thick portion overlapping a bending area DA_F defined between display areas radially adjacent to each other. Thus, even though the display panel DP according to an embodiment of the invention includes the display area DA at the front surface and at the four side surfaces based on the rectangular parallelepiped shape, the strain or stress of the bending area DA_F, which is applied to the display panel DP, may be relatively reduced to provide the display panel DP having the improved durability. When the encapsulation layer TFE according to an embodiment of the invention includes the laminated structure in which the organic layer is disposed between two inorganic layers, the bending stress applied to the inorganic layer disposed to be furthest from the base layer may be relatively large. However, in the encapsulation layer TFE according to an embodiment of the invention, the bending area DA_F may have the relatively large thickness as compared to a remaining area of the encapsulation layer TFE. Thus, the display panel DP including the encapsulation layer TFE and the display device DD having the display panel DP may be improved in reliability.

The display panel DP according to the invention may include the encapsulation layer TFE having the improved reliability to improve the durability.

The display device DD according to the invention may include the display panel DP having the encapsulation layer TFE to improve the display quality.

It will be apparent to those skilled in the art that various modifications and variations can be made in the invention. Thus, it is intended that the present disclosure covers the modifications and variations of this invention provided they come within the scope of the appended claims and their equivalents. Therefore, the technical scope of the invention is not limited to the contents described in the detailed description of the specification, but should be determined by the claims.

What is claimed is:

1. A display panel comprising:
a display area comprising a front area and a bending area which is bent from a first side of the front area to have a first curvature, and a non-display area which is adjacent to the display area;
a base layer;
a circuit layer on the base layer;
a light emitting element layer on the circuit layer, the light emitting element layer comprising a light emitting element overlapping the display area; and
an encapsulation layer on the light emitting element layer,
wherein the encapsulation layer comprises:
a first thickness portion overlapping the front area,
a second thickness portion overlapping the bending area, and
a first distance from a top surface of the base layer to a top surface of the encapsulation layer at the first thickness portion which is less than a second distance from the top surface of the base layer to a top surface of the encapsulation layer at the second thickness portion.

2. The display panel of claim 1, wherein the top surface of of the encapsulation layer at the second thickness portion is curved.

3. The display panel of claim 1, wherein the display area further comprises the front area, the bending area and a side area in order.

4. The display panel of claim 3, wherein
the light emitting element generates light in a visible light wavelength range, and
the light which is in the visible light wavelength range is emitted through the front area, the bending area and the side area of the display area.

5. The display panel of claim 3, wherein the encapsulation layer further comprises:
a third thickness portion overlapping the side area, and
the first distance which is less than a third distance from the top surface of the base layer to a top surface of the encapsulation layer at the third thickness portion.

6. The display panel of claim 1, wherein each of the first thickness portion and the second thickness portion of the encapsulation layer comprises:
a first inorganic layer on the light emitting element layer,
a first organic layer on the first inorganic layer, and
a second inorganic layer on the first organic layer.

7. The display panel of claim 6, wherein the second thickness portion of the encapsulation layer which overlaps the bending area further comprises a third inorganic layer on the second inorganic layer.

8. The display panel of claim 7, wherein the second distance is defined from the top surface of the base layer to a top surface of the third inorganic layer.

9. The display panel of claim 6, wherein the second thickness portion of the encapsulation layer which overlaps the bending area further comprises a second organic layer on the second inorganic layer.

10. The display panel of claim 9, wherein the second distance is defined from the top surface of the base layer to a top surface of the second organic layer.

11. The display panel of claim 9, wherein the second organic layer overlaps an entirety of the bending area and has a dome shape which is convex in a direction away from the second inorganic layer.

12. The display panel of claim 9, wherein
the second thickness portion of the encapsulation layer which overlaps the bending area further comprises a third inorganic layer on the second organic layer, and
the second distance is defined from the top surface of the base layer to a top surface of the third inorganic layer.

13. The display panel of claim 9, wherein
the display area further comprises the front area, the bending area and a side area in order, and
within the encapsulation layer:
the second organic layer extends from the bending area to the side area to overlap the side area, and
a distance from the top surface of the base layer to a top surface of the second organic layer at the side area is less than a distance from the top surface of the base layer to a top surface of the second organic layer at the bending area.

14. The display panel of claim 1, wherein the bending area comprises:
a first bending active area bent from the first side of the front area to have the first curvature; and
a second bending active area bent from a second side of the front area which intersects the first side of the front area, the second bending active area having a second curvature.

15. The display panel of claim 14, wherein within the encapsulation layer, the second thickness portion comprises:
a second-1 portion overlapping the first bending active area,
a second-2 portion overlapping the second bending active area, and
the first distance which is less than each of a distance from the top surface of the base layer to a top surface of the encapsulation layer at the second-1 portion and a distance from the top surface of the base layer to a top surface of the encapsulation layer at the second-2 portion.

16. The display panel of claim 1, wherein the encapsulation layer has light transmittance of about 80% or more in a visible light wavelength range.

17. The display panel of claim 1, wherein the encapsulation layer is directly on the light emitting element layer.

18. The display panel of claim 1, wherein the light emitting element comprises a first electrode, an emission layer and a second electrode.

19. A display panel comprising:
a display area comprising a front area and a bending area which is bent from a side of the front area to have a curvature;
a base layer;
a circuit layer on the base layer;
a light emitting element layer on the circuit layer, the light emitting element layer comprising a light emitting element overlapping the display area; and
an encapsulation layer on the light emitting element layer,
wherein the encapsulation layer comprises:
a first inorganic layer, a first organic layer and a second inorganic layer in order from the light emitting element layer,
a first thickness portion overlapping the front area,
a second thickness portion overlapping the bending area, and
a first distance from a top surface of the base layer to a top surface of the encapsulation layer at the first thickness portion which is less than a second distance from the top surface of the base layer to a top surface of the encapsulation layer at the second thickness portion.

20. A display device comprising:
a display panel which emits light;
an input sensing layer including an input sensor, on the display panel; and
a window on the input sensing layer,
wherein the display panel comprises:
a display area comprising a front area and a bending area which is bent from a side of the front area to have a curvature;
a non-display area adjacent to the display area;
a base layer;
a circuit layer on the base layer;
a light emitting element layer on the circuit layer, the light emitting element layer comprising a light emitting element overlapping the display area; and
an encapsulation layer on the light emitting element layer, the encapsulation layer comprising:
a first thickness portion overlapping the front area,
a second thickness portion overlapping the bending area, and
a first distance from a top surface of the base layer to a top surface of the encapsulation layer at the first thickness portion which is less than a second distance from the top surface of the base layer to a top surface of the encapsulation layer at the second thickness portion.
